(19) United States
(12) Patent Application Publication
(10) Pub. No.: US 2020/0090746 A1
(43) Pub. Date: Mar. 19, 2020

(54) NONVOLATILE MEMORY DEVICE FOR INVALIDATING DATA STORED THEREIN, MEMORY SYSTEM INCLUDING THE SAME, AND OPERATING METHOD THEREOF

(71) Applicant: SK hynix Inc., Gyeonggi-do (KR)

(72) Inventors: Jung-Hyun KWON, Seoul (KR); Jae-Min JANG, Seoul (KR); Sang-Gu JO, Gyeonggi-do (KR)

(21) Appl. No.: 16/232,142

(22) Filed: Dec. 26, 2018

(30) Foreign Application Priority Data
Sep. 18, 2018 (KR) 10-2018-0111538

(51) Int. Cl. G11C 13/00; G06F 3/06

(52) U.S. Cl. CPC G11C 13/0059; G11C 13/0004; G11C 13/003; G11C 13/0028; G11C 13/0026; G11C 13/004; G06F 3/062; G06F 3/0638; G06F 3/0673; G11C 13/0069; G11C 13/0061

(57) ABSTRACT

A memory device includes a plurality of word lines and a plurality of bit lines intersecting the word lines, a memory cell array comprising a plurality of memory cells coupled between the word lines and the bit lines at intersections between the word lines and the bit lines, respectively, an address decoder suitable for decoding an address to access a memory cell selected among the memory cells, and a controller suitable for writing and reading data to and from the selected memory cell by applying voltages to the word lines and bit lines, wherein the controller invalidates data stored in memory cells coupled to a target word line among the word lines by applying an invalidation voltage to the target word line for a set time.

### CROSS-REFERENCE TO RELATED APPLICATION

This application claims priority under 35 U.S.C. §119 to Korean Patent Application No. 10-2018-0111538 filed on Sep. 18, 2018, which is incorporated herein by reference in its entirety.

### BACKGROUND

### 1. Field

Exemplary embodiments relate to a nonvolatile memory device, and more particularly, to a nonvolatile memory device capable of invalidating data stored therein and a memory system including the nonvolatile memory device.

### 2. Discussion of the Related Art

Memory systems are applied to various electronic devices for consumer or industry use, for example, a computer, mobile phone, portable digital assistant (PDA), digital camera, game machine, navigation system and the like, and used as a main memory or auxiliary memory (storage). The memory systems may be implemented with various types of memory devices. The memory devices are divided into volatile memory devices and nonvolatile memory devices. The volatile memory devices may include a dynamic random access memory (DRAM) and a static RAM (SRAM), and the nonvolatile memory devices may include a read only memory (ROM), a mask ROM (MROM), programmable ROM (PROM), an erasable programmable ROM (EPROM), an electrically erasable programmable ROM (EEPROM), a ferroelectric RAM (FRAM), a phase-change RAM (PRAM), a magnetoresistive RAM (MRAM), a resistive RAM (RRAM) and a flash memory.

When power supply is cut off, data stored in the volatile memory device may not be retained but lost. On the other hand, the nonvolatile memory device retains data stored therein even though power supply is cut off. Therefore, the nonvolatile memory device may selectively store data in a volatile memory region and a nonvolatile memory region, depending on the usage of data requested by a host.

For example, when data requiring security are continuously retained in the nonvolatile memory device while power supply is cut off, the data are highly likely to be exposed to other users. As a result, the data inevitably become vulnerable to security threats. The nonvolatile memory device needs to store such data in the volatile memory region, and invalidate the data stored in the volatile memory region when power supply is cut off.

### SUMMARY

Various embodiments are directed to a memory device capable of invalidating data of memory cells coupled to a word line of the memory device by supplying an invalidation voltage to the word line, and an operation method thereof.

In an embodiment of the present invention, a memory device includes: a plurality of word lines and a plurality of bit lines intersecting the plurality of word lines; a memory cell array comprising a plurality of memory cells coupled between the plurality of word lines and the plurality of bit lines at intersections between the plurality of word lines and the plurality of bit lines, respectively; an address decoder suitable for decoding an address to access a memory cell selected among the plurality of memory cells; and a controller suitable for writing and reading data to and from the selected memory cell by applying voltages to the plurality of word lines and bit lines, wherein the controller invalidates data stored in memory cells coupled to a target word line among the plurality of word lines by applying an invalidation voltage to the target word line for a set time.

In an embodiment of the present invention, a memory system includes: a memory device comprising a plurality of memory cells coupled between a plurality of word lines and a plurality of bit lines, and suitable for writing and reading data to and from a selected memory cell among the plurality of memory cells; and a memory controller suitable for detecting a power supply voltage of the memory device to generate an invalidation command, wherein the memory device invalidates data stored in memory cells coupled to a target word line among the plurality of word lines by applying an invalidation voltage to the target word line for a set time, in response to the invalidation command.

In an embodiment of the present invention, an operating method of a memory system including a memory device and a memory controller includes: determining, by the memory controller, whether to invalidate data stored in a memory device, by detecting a level of a power supply voltage of the memory device; and invalidating, by the memory controller, data stored in memory cells coupled to a target word line among a plurality of word lines of the memory device by applying an invalidation voltage to the target word line for a set time, based on the determination result.

### BRIEF DESCRIPTION OF THE DRAWINGS

FIG. 1 is a block diagram illustrating a memory system in accordance with an embodiment of the present invention.

FIG. 2A is a detailed diagram illustrating a memory device in accordance with an embodiment of the present invention.

FIG. 2B is a detailed diagram illustrating a memory device in accordance with an embodiment of the present invention.

FIGS. 3A and 3B are detailed diagrams illustrating a memory cell array shown in FIG. 2A and 2B.

FIG. 4 is a waveform diagram for describing operations of the memory cell arrays shown in FIGS. 3A and 3B.

FIG. 5 is a flowchart for describing an operation of a memory system in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Moreover, detailed descriptions related to well-known functions or configurations will be omitted in order to clearly describe the subject matters of the present invention. is Throughout the disclosure, like reference numerals refer to like parts throughout the various figures and embodiments of the present invention.

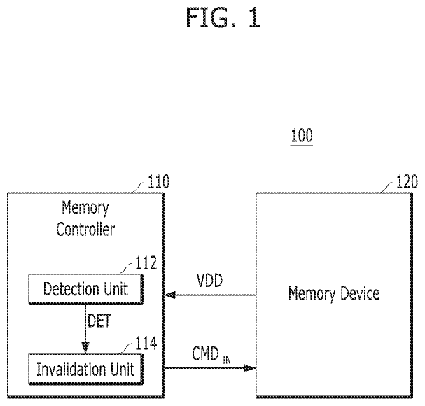

FIG. 1 is a block diagram illustrating a memory system 100 in accordance with an embodiment of the present invention. Referring to FIG. 1, the memory system 100 may include a memory controller 110 and a memory device 120.

When the memory device 120 is powered off, the memory controller 110 may invalidate data stored in the memory device 120. The memory controller 110 may invalidate data stored in a specific region of the memory device 120. In accordance with the embodiment of the present invention, the memory controller 110 may detect a power-off of the memory device 120.

The memory controller 110 may include a detection unit 112 and an invalidation unit 114. The detection unit 112 may detect a power-off of the memory device 120. When a power supply voltage VDD of the memory device 120 falls below a reference level, the detection unit 112 may generate a detection signal DET. For example, when the power supply voltage VDD of the memory device 120 is cut off or a power drop occurs, the detection unit 112 may generate the detection signal DET.

In response to the detection signal DET, the invalidation unit 114 may generate an invalidation command CMD_{IN} for invalidating data stored in the memory device 120. When the detection signal DET is activated by the detection unit 112, the invalidation unit 114 may generate the invalidation command CMD_{IN} and provide the generated invalidation command CMD_{IN} to the memory device 120. In accordance with the embodiment of the present invention, the memory device 120 may invalidate data stored in a specific region in response to the invalidation command CMD_{IN}.

The memory device 120 may include a nonvolatile memory device, for example, a PCRAM. However, the present invention is not limited thereto.

The memory device 120 may include a volatile memory region and a nonvolatile memory region. The memory device 120 may write and store input data, and read and output data stored therein, under control of the memory controller 110. In particular, the memory device 120 may store some of the input data, for example, security data in the volatile memory region. In accordance with embodiments, the volatile memory region may be set (or allocated) by the memory controller 110 or the memory device 120.

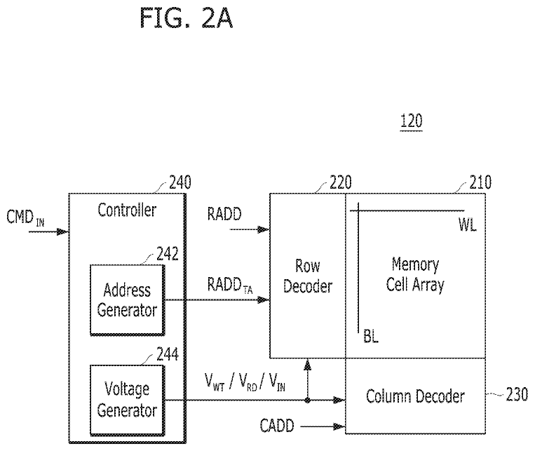

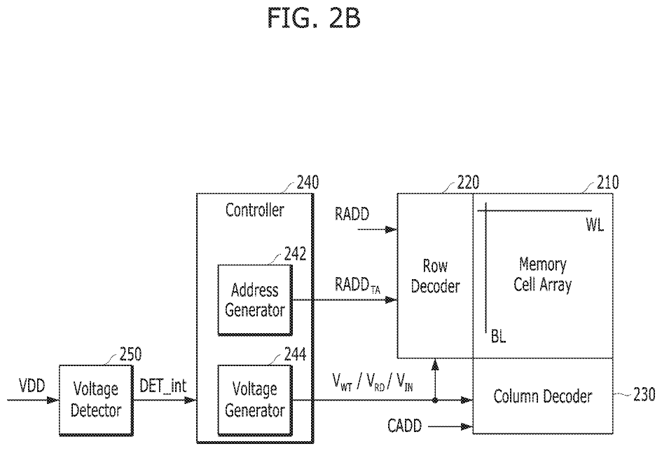

FIG. 2A is a detailed diagram of the memory device 120 shown in FIG. 1. Referring to FIG. 2A, the memory device 120 may include a memory cell array 210 having a plurality of memory cells, address decoders 220 and 230, and a controller 240.

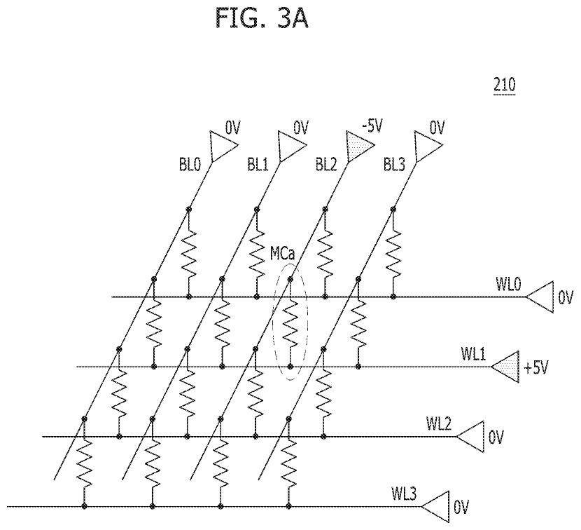

The memory cell array 210 may include a plurality of word lines WL and a plurality of bit lines BL intersecting the plurality of word lines WL. The memory cell array 210 may include a plurality of memory cells provided at the respective intersections between the word lines WL and the bit lines BL. The structure of the memory cell array 210 will be described in more detail with reference to FIG. 3.

The address decoders 220 and 230 may decode addresses to access a memory cell selected among the plurality of memory cells of the memory cell array 210. The address decoders 220 and 230 may include a row decoder 220 and a column decoder 230. The row decoder 220 may select a word line corresponding to a memory cell selected by decoding a row address RADD to apply a voltage to the selected word line, and the column decoder 230 may select a bit line corresponding to a memory cell selected by decoding a column address CADD to apply a voltage to the selected bit line.

The controller 240 may apply voltages to the word line and bit line corresponding to the selected memory cell, among the plurality of word lines WL and bit lines BL, through the row decoder 220 and the column decoder 230. The controller 240 may generate a voltage V_{WT} corresponding to a write operation and a voltage V_{RD} corresponding to a read operation, and provide the generated voltage to the row decoder 220 and the column decoder 230. The voltages V_{WT} and V_{RD} provided to the row decoder 220 and the column decoder 230 may be applied to the word line and bit line corresponding to the selected memory cell, such that data may be written to or read from the selected memory cell. Each of the voltages V_{WT} and V_{RD} may include a voltage for the word lines WL and a voltage for the bit lines BL.

In accordance with the embodiment of the present invention, the controller 240 may invalidate data stored in memory cells coupled to a target word line among the plurality of word lines WL. For example, when the invalidation command CMD_{IN} is inputted to the memory device 120 from the memory controller 110, the controller 240 may apply the invalidation voltage V_{IN} to the target word line for a predetermined time, in order to invalidate the data stored in the memory cells coupled to the target word line.

Referring to FIG. 2A, the controller 240 may include an address generator 242 and a voltage generator 244. The address generator 242 may generate a row address RADD_{TA} indicating the target word line in response to the invalidation command CDM_{IN}. When the row address RADD_{TA} is inputted from the address generator 242, the row decoder 220 may access the target word line corresponding to the row address RADD_{TA}.

The voltage generator 244 may generate the invalidation voltage V_{IN} for a predetermined time, in response to the invalidation command CMD_{IN}. The invalidation voltage VIN generated from the voltage generator 244 may be supplied to the target word line through the row decoder 220.

FIG. 2B is a block diagram illustrating a memory device in accordance with an embodiment of the present invention. Referring to FIG. 2B, the memory device may include the memory cell array 210, the address decoders 220 and 230, and the controller 240. The is memory device may further include a voltage detector 250 for detecting a level of the power supply voltage VDD. When a level of the power supply voltage VDD falls below the reference level, the voltage detector 250 may internally generate a detection signal DET_int. In this case, the controller 240 does not need to receive invalidation command CMD_{IN}, and the detection unit 112 may be removed from the memory controller 110.

In response to the detection signal DET_int, the controller 240 may apply the invalidation voltage V_{IN}to the target word line among the plurality of word lines WL for a predetermined time, in order to invalidate the data stored in the memory cells coupled to the target word line. Since the operation of the controller 240 based on the detection signal DET_int is similar to the above-described operation based on the invalidation command CMD_{IN}, the duplicated descriptions will be omitted herein.

FIGS. 3A and 3B are circuit diagrams of the memory cell array 210 shown in FIG. 2A and 2B. The memory cell array 210 may have an X-point structure in which a plurality of memory cells are coupled between a plurality of word lines WL0 to WL3 and a plurality of bit lines BL0 to BL3 at the respective intersections between the word lines and the bit lines. For example, the plurality of memory cells are PCRAM

FIG. 3A describes a write operation performed on the memory cell array 210. For example, one memory cell MCa of the plurality of memory cells may be selected, and a write operation may be performed on the selected memory cell MCa. In order to write data to the selected memory cell MCa, write voltages may be applied to the second word line WL1 and the third bit line BL2, respectively, which correspond to the selected memory cell MCa.

Referring to FIG. 3A, a voltage of 5V may be applied to the second word line WL1, and a voltage of −5V may be applied to the third bit line BL2. Therefore, a voltage of 10V may be applied across the selected memory cell MCa, such that the selected memory cell MCa has ‘SET’ resistance state.

However, as the voltages are applied to the second word line WL1 and the third bit line BL2, a predetermined voltage may be applied across other memory cells as well as the selected memory cell MCa. That is, a voltage of 5V may be applied to the other memory cells excluding the selected memory cell MCa among memory cells coupled to the second word line WL1. Similarly, a voltage of 5V may be applied to the other memory cells excluding the selected memory cell MCa among memory cells coupled to the third bit line BL2.

As such, the write operation for the selected memory cell MCa may cause inhibit-disturb to apply a voltage to the adjacent memory cells. When the memory cells are exposed to such inhibit-disturbance frequently or for a long time, data of the memory cells may be changed. Based on such a phenomenon, the data of the memory cells may be rapidly invalidated.

FIG. 3B describes the invalidation operation performed on the memory cell array 210. For example, data stored in memory cells MCb coupled to the second word line WL1 may be invalidated. Referring to FIG. 3B, a voltage of 5V may be applied to the second word line WL1, and a voltage of 0V may be applied to the other word lines WL1, WL2 and WL3 and the bit lines BL0, BL1, BL2 and BL3. Therefore, a voltage of 5V may be applied across the memory cells MCb coupled to the second word line WL1.

The invalidation operation of FIG. 3B may invalidate the data stored in the memory cells MCb coupled to the second word line WL1 by applying a voltage of 5V once to the second word line WL1. Therefore, since the voltage is not applied to each of the memory cells MCb coupled to the second word line WL1, the time required for the invalidation operation may be reduced. Furthermore, the invalidation operation may invalidate the data stored in the memory cells MCb, using a write operation voltage of 5V as it is.

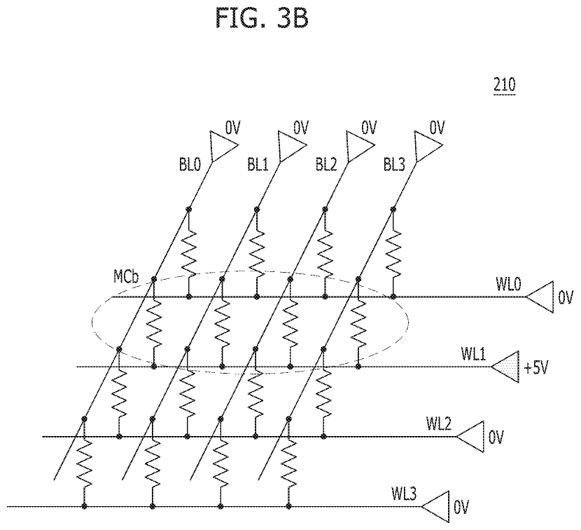

FIG. 4 is a waveform diagram comparatively illustrating the operations of the memory cell arrays 210 of FIGS. 3A and 3B. FIG. 4 representatively illustrates an operation of one word line WL1 of the memory cell array 210.

For example, when K memory cells are coupled to the second word line WL1, K write operations may be performed in order to delete data of the memory cells coupled to the second word line WL1. Referring to ‘SET’ of FIG. 4, a voltage of 5-(−5) V for the write operations may be sequentially applied to the K memory cells. When 1,000 memory cells are coupled to the second word line WL1 and the write latency of each memory cell is 500 ns, a time of 500 us (1,000*500 ns) may be required to delete data of the memory cells coupled to the second word line WL1.

In accordance with the embodiment of the present invention, however, the data of the memory cells coupled to the second word line WL1 may be deleted by one invalidation operation, regardless of the number of the memory cells coupled to the second word line WL1. That is, referring to ‘INVALIDATION’ of FIG. 4, the same voltage of 5V may be applied to all of the memory cells coupled to the second word line WL1 through the second word line WL1 at the same time. Thus, one voltage application operation may invalidate all of the data stored in the memory cells coupled to the second word line WL1.

Compared to the write operation, the magnitude of the voltage applied to the memory cells may be lowered from 10V to 5V, because a voltage of 5V is applied only to the word line. Instead, the time required for applying the voltage to the memory cells may be longer than the write latency of 500 ns. That is, as the plurality of memory cells are invalidated together, a sufficient time of 1,200 ns may be required for changing the data of the memory cells, while the voltage applied to the memory cells is reduced. The present invention is not limited thereto, but the invalidation voltage of 5V and the required time of 1,200 ns may be adjusted depending on the power consumption of the memory device 120.

As described above, the memory device 120 may include a nonvolatile memory device. Therefore, the memory device 120 may separately store and manage data which need to be deleted when power supply is cut off, for example, security data. The memory device 120 may set (or allocate) a volatile memory region, to store the security data in the volatile memory region. When power is cut off, the memory device 120 may invalidate the data stored in the volatile memory region.

Thus, the target word line where the invalidation operation is performed may correspond to the volatile memory region. During the initial operation, the memory device 120 may set the volatile memory region to store the row address RADD_{TA} corresponding to the target word line. The address generator 242 of the controller 240 may include a register or the like, and store the row address RADD_{TA} corresponding to the target word line.

In accordance with another embodiment, the memory controller 110 may allocate the volatile memory region of the memory device 120. At this time, the invalidation unit 114 may store a row address corresponding to the target word line, and provide the stored row address along with the invalidation command CMD_{IN}, to the memory device 120.

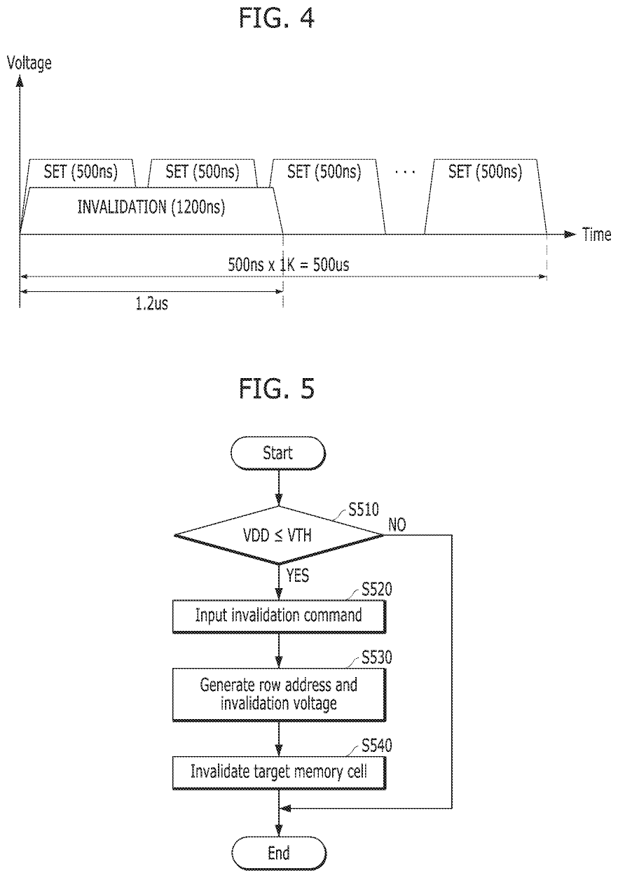

FIG. 5 is a flowchart for describing an operation of the memory system in accordance with an embodiment of the present invention.

### 1) Invalidation Determination Operation.

The memory controller 110 may detect the power supply voltage VDD of the memory device 120, and determine whether to invalidate data stored in the memory device 120. For this operation, the memory controller 110 may compare the power supply voltage VDD of the memory device 120 to a threshold level (i.e., a reference level) VTH at step S510. When the comparison result indicates that the power supply voltage VDD of the memory device 120 is equal to or less than the threshold level (YES at step S510), the memory controller 110 may generate the invalidation command CMD_{IN} and input the generated invalidation command to the memory device 120 at step S520.

### 2) Data Invalidation Operation.

In response to the invalidation command CMD_{IN}, the memory device 120 may generate the invalidation voltage VIN and the row address RADD_{TA} indicating the target word line, at step S530. The memory device 120 may supply the invalidation voltage VIN to the target word line for a predetermined time, based on the row address RADD_{TA}. The memory device 120 may invalidate data of target memory cells coupled to the target word line by supplying the invalidation voltage V_{IN} to the target word line for more than a time corresponding to the write latency, at step 5540.

In accordance with the embodiments of the present invention, the memory system may rapidly invalidate data requiring security among data stored in a nonvolatile memory device. The memory system may delete data of a plurality of memory cells of the nonvolatile memory device at once by applying an invalidation voltage to a word line, without accessing the data stored in the plurality of memory cells one by one. Therefore, the memory system may reduce the time required for deleting security data stored in the plurality of memory cells. The memory system may detect the power supply voltage of the nonvolatile memory device, and perform the invalidation operation based on the detected power supply voltage, thereby rapidly removing a large quantity of security data when the nonvolatile memory device is powered off.

Although various embodiments have been described for illustrative purposes, it will be apparent to those skilled in the art that various changes and modifications may be made without departing from the spirit and scope of the invention as defined in the following claims.

What is claimed is:

1. A memory device comprising:
a plurality of word lines and a plurality of bit lines intersecting the plurality of word lines;
a memory cell array comprising a plurality of memory cells coupled between the plurality of word lines and the plurality of bit lines at intersections between the plurality of word lines and the plurality of bit lines, respectively;
an address decoder suitable for decoding an address to access a memory cell selected among the plurality of memory cells; and
a controller suitable for writing and reading data to and from the selected memory cell by applying voltages to the plurality of word lines and bit lines,
wherein the controller invalidates data stored in memory cells coupled to a target word line among the plurality of word lines by applying an invalidation voltage to the target word line for a set time.

2. The memory device of claim 1, wherein the controller comprises:
an address generator suitable for generating a row address indicating the target word line in response to an invalidation command externally inputted; and
a voltage generator suitable for generating the invalidation voltage for the set time, in response to the invalidation command.

3. The memory device of claim 1, further comprising:
a voltage detector suitable for detecting a level of a power supply voltage, and generating a detection signal activated when a level of the power supply voltage falls below a threshold level.

4. The memory device of claim 3, wherein the controller comprises:
an address generator suitable for generating a row address indicating the target word line in response to the detection signal; and
a voltage generator suitable for generating the invalidation voltage for the set time, in response to the detection signal.

5. The memory device of claim 1, wherein the address decoder comprises:
a row decoder suitable for decoding a row address to select a word line corresponding to the selected memory cell, and applying a voltage corresponding to an operation to be performed, to the selected word line; and
a column decoder suitable for decoding a column address to select a bit line corresponding to the selected memory cell, and applying a voltage corresponding to the operation to be performed, to the selected bit line.

6. The memory device of claim 1, wherein the set time is longer than a time corresponding to write latency of the memory device.

7. The memory device of claim 1, wherein the memory cell array comprises a volatile memory region and a nonvolatile memory region, and the target word line is coupled to memory cells included in the volatile memory region, among the plurality of memory cells.

8. The memory device of claim 7, wherein the memory device stores security data, which are to be deleted when a power supply voltage is cut off, in the volatile memory region.

9. A memory system comprising:
a memory device comprising a plurality of memory cells coupled between a plurality of word lines and a plurality of bit lines, and suitable for writing and reading data to and from a memory cell selected among the plurality of memory cells; and
a memory controller suitable for detecting a power supply voltage of the memory device to generate an invalidation command,
wherein the memory device invalidates data stored in memory cells coupled to a target word line among the plurality of word lines by applying an invalidation voltage to the target word line for a set time, in response to the invalidation command.

10. The memory system of claim 9, wherein the memory controller comprises:
a detection unit suitable for generating a detection signal activated when a level of the power supply voltage falls below a threshold level; and
an invalidation unit suitable for generating the invalidation command in response to the detection signal.

11. The memory system of claim 10, wherein the memory device comprises:
an address generator suitable for generating a row address indicating the target word line in response to the invalidation command; and
a voltage generator suitable for generating the invalidation voltage for the set time, in response to the invalidation command.

12. The memory system of claim 10, wherein the invalidation unit stores a row address indicating the target word line, and provides the row address along with the invalidation command, to the memory device.

13. The memory system of claim 12, wherein in response to the invalidation command and the row address, the memory device applies the invalidation voltage to the target word line corresponding to the row address for the set time.

14. The memory system of claim 9, wherein the set time is longer than a time corresponding to write latency of the memory device.

15. The memory system of claim 9, wherein the plurality of memory cells are included in a volatile memory region and a nonvolatile memory region, and the target word line is coupled to memory cells included in the volatile memory region among the plurality of memory cells.

16. The memory system of claim 15, wherein the memory device stores data, which security are to be deleted when the power supply voltage is cut off, in the volatile memory region.

17. An operating method of a memory system including a memory device and a memory controller, the operating method comprising:
determining, by the memory controller, whether to invalidate data stored in a memory device, by detecting a level of a power supply voltage of the memory device; and
invalidating, by the memory device, data stored in memory cells coupled to a target word line among a plurality of word lines of the memory device by applying an invalidation voltage to the target word line for a set time, based on the determination result.

18. The operating method of claim 17, wherein the determining of whether to invalidate the data stored in the memory device comprises:
comparing the power supply voltage to a threshold level; and
providing an invalidation command to the memory device when the power supply voltage is determined to be equal to or less than the threshold level.

19. The operating method of claim 18, wherein the invalidating of the data stored in the memory cells coupled to the target word comprises:
generating a row address indicating the target word line and the invalidation voltage, in response to the invalidation command; and
supplying the invalidation voltage to the target word line for the set time, based on the row address.

20. The operating method of claim 17, wherein the set time is longer than a time corresponding to write latency of the memory device.
